(19) United States
(12) Patent Application Publication
(10) Pub. No.: US 2008/0144378 A1
(43) Pub. Date: Jun. 19, 2008

(54) NONVOLATILE SEMICONDUCTOR MEMORY DEVICE HAVING REDUCED ELECTRICAL STRESS

(75) Inventors: Ki-Tae PARK, Seongnam-si (KR); Seung-Chul LEE, Seongnam-si (KR); Ki-Nam KIM, Gangnam-gu (KR)

Correspondence Address: VOLENTINE & WHITT PLLC, ONE FREEDOM SQUARE, 11951 FREEDOM DRIVE SUITE 1260, RESTON, VA, 20190, US

(73) Assignee: SAMSUNG ELECTRONICS CO., LTD., Suwon-si (KR)

(21) Appl. No.: 11/947,007

(22) Filed: Nov. 29, 2007

(30) Foreign Application Priority Data
Dec. 14, 2006 (KR) 10-2006-0127849

(51) Int. Cl. G11C 11/40

(52) U.S. Cl. 365/185.05

(57) ABSTRACT

A nonvolatile semiconductor memory includes a floating formation switch coupled to a bit line in a memory cell array. The floating formation switch maintains a channel voltage of memory cells coupled to the bit line at a level above a power supply voltage when the bit line is a non-selected bit line, which reduces electrical stress applied to the memory cells connected to the non-selected bit line during a read operation.

### CROSS-REFERENCE TO RELATED PATENT APPLICATION

A claim of priority is made to Korean Patent Application No. 10-2006-0127849, filed on Dec. 14, 2006, the subject matter of which is hereby incorporated by reference.

### BACKGROUND OF THE INVENTION

1. Field of the Invention

The present invention relates to a semiconductor memory. More particularly, the present invention relates to a nonvolatile semiconductor memory having reduced electrical stress during a read operation.

2. Description of the Related Art

Recent rapid developments in information processing devices have tended to increase the need for higher speed operations and larger storage capacities in semiconductor memory devices used as components within the information processing devices. Typically semiconductor memory devices are classified as volatile semiconductor memory devices or nonvolatile semiconductor memory devices.

A volatile semiconductor memory device may be classified as a dynamic random access memory or a static random access memory. A volatile semiconductor memory device has fast read and write speeds. However, contents stored in memory cells of the volatile semiconductor memory device are lost when external power supply is cut off.

A nonvolatile semiconductor memory device may be classified as a mask read only memory (MROM), a programmable read only memory (PROM), an erasable programmable read-only memory (EPROM), an electrically erasable programmable read-only memory (EEPROM), etc. Such nonvolatile semiconductor memory devices have been typically used to store contents that must be preserved even when external power is removed because nonvolatile memories can permanently keep contents within memory cells, regardless of power. However, with respect to the MROM, PROM and EPROM, general users are not free to execute erase and write (or program) operations using the electronic system itself. In other words, it is difficult to erase or re-program programmed-contents in an on-board state. In contrast, an EEPROM may be used in a system program storage device or auxiliary storage device, which needs its contents continuously updated, because erase and write operations are validated by the system itself.

Many electronic devices controlled by a computer or micro-processor incorporate EEPROMs due to their high density and electrically erasable and programmable capabilities. Moreover, a data storage device, such as a digital camera etc., must be compact in the size. However, a hard disk device having a rotary magnetic disk and being used as an auxiliary memory device in a battery-powered computer system, such as a portable computer or notebook computer, needs to occupy a relatively large space. Therefore, designers of these systems are typically interested in EEPROMs, which occupy a relatively small area and have a relatively high density and performance.

A flash EEPROM, e.g., having a flash erase function, has been developed as advancements have been made in EEPROM design and manufacturing technology. A flash EEPROM has a higher integration level than a general EEPROM, and is desirable for use as a large-capacity auxiliary memory device. The flash EEPROM is classified as a NAND, NOR or AND type depending on the corresponding type of unit memory cell arrays. It is well known that the NAND type flash EEPROM has a higher integration level than the NOR or AND types.

FIG. 1 is a block diagram of a conventional nonvolatile semiconductor memory device. FIG. 1 illustrates configuration of blocks of a NAND-type EEPROM, including a memory cell array 1, a sense amplifier and latch 2 for sensing and storing input/output data of memory cell transistors, a column decoder 3 for selecting bit lines, an input/output buffer 4, a row decoder 5 for selecting word lines, an address register 6, a high voltage generating circuit 8 for generating a high voltage higher than a power supply voltage, and a control circuit 7 for controlling operation of a memory device.

FIG. 2A is a circuit diagram of an equivalent circuit illustrating the structure of memory cells within the memory cell array 1 of FIG. 1. The memory cell array 1 actually includes multiple cell strings or NAND cell units, but for convenience of explanation, FIG. 2A shows only a first cell string 1a coupled to an even bit line BLe and a second cell string 1b coupled to an odd bit line BLo.

The first cell string 1a includes a string selection transistor SST1 having a drain coupled to a bit line BLe, a ground selection transistor GST1 having a source coupled to a common source line CSL, and multiple memory cell transistors MC31a, MC30a, . . . , MC0a having drain-source channels connected in series between a source of the string selection transistor SST1 and a drain of the ground selection transistor GST1. Similarly, the second cell string 1b includes a string selection transistor SST2 having a drain coupled to bit line BLo, a ground selection transistor GST2 having a source coupled to common source line CSL, and multiple memory cell transistors MC31b, MC30b, . . . , MC0b having drain-source channels connected in series between a source of the string selection transistor SST2 and a drain of the ground selection transistor GST2.

A signal applied to a string selection line SSL is supplied in common to gates of the string selection transistors SST1 and SST2, and a signal applied to a ground selection line GSL is supplied in common to gates of the ground selection transistors GST1 and GST2. Word lines WL0-WL31 are individually coupled equivalently in common to control gates of memory cell transistors on the same row. The bit lines BLe and BLo, which are operationally connected to the sense amplifier and latch 2 of FIG. 1, run perpendicular to and on a different layer different from the word lines WL0-WL31. The bit lines BLe and BLo are parallel with one another on the same layer.

FIG. 2B illustrates an example of bias voltage applied to the equivalent circuit of FIG. 2A in a read operating mode, i.e., for performing a read operation. For example, when the even-bit line BLe is selected during a read operation, an applied precharge voltage of 0.7V, for example, is applied to the selected even bit line BLe and a noise shielding voltage of 0V, for example, is applied to the non-selected odd bit line BLo. In this case, when a memory cell transistor MC0a of the first cell string 1a is selected, a selection read voltage Vr is applied to selected word line WL0, and a read voltage Vread is applied to the non-selected word lines WL1-WL31, the string selection line SSL and the ground selection line GSL. Further, 0V is applied to a common source line CSL.

Data stored in memory cell transistor MC0a of the selected first cell string 1a is sensed and a read operation is performed, based on the voltage bias described above. More particularly, when the string selection transistor SST1, the ground selection transistor GST1 and the memory cell transistors MC01-MC31a are turned ON, the voltage of selection bit line BLe is discharged to a level of 0V or a determined voltage is maintained nearly intact, according to a threshold voltage value of the memory cell transistor MC0a. When a threshold voltage of the selection memory cell transistor is lower than a reference value, a current path of from the selection bit line BLe to the common source line CSL is formed and so the selection bit line BLe is discharged to a lower level. Thus, the sense amplifier connected to the selection bit line BLe senses a selection memory cell transistor as an on-cell, data 0 or 1. When electrons are injected into a floating gate of the selection memory cell, such that a threshold voltage is higher than a reference value, a current path from the selection bit line BLe to the common source line CSL is not formed, so voltage precharged to the selection bit line BLe is maintained almost its level state. At this time, the sense amplifier connected to the selection bit line BLe senses a selection memory cell as an off-cell, data 1 or 0.

In the read operating mode described above, the read voltage Vread is also applied to control gates of memory cell transistors MC31b, MC30b, . . . , MC1b, provided in second cell string 1b coupled to non-selected bit line BLo. In other words, the non-selected memory cell transistors MC31b, MC30b, . . . , MC1b:A have electrical stress. A read disturbance is caused by the electrical stress, as discussed in reference to FIG. 3.

FIG. 3 shows related-voltage stress in respective memory cells connected to a selected-bit line and a non-selected bit line, for example, as shown in FIG. 2B. In the drawing on the left in FIG. 3, a memory cell transistor MCib indicates any one of the non-selected memory cell transistors MC31b, MC30b, . . . , MC1b:A in the second cell string 1b of FIG. 2B. In the drawing on the right in FIG. 3, a memory cell transistor MCia indicates any one of the non-selected memory cell transistors MC31a, MC30a, . . . , MC1a connected to the selected bit line BLe of FIG. 2B.

For example, it may be assumed that a threshold voltage of a memory cell transistor is about −3V and a coupling ratio indicating a rate of capacitance is about 0.5, the rate of capacitance corresponding to an interlayer dielectric layer 19, such as ONO, etc., formed below a control gate 20, and a gate insulation layer 16, such as a gate oxide layer, etc., formed below a floating gate 18. It may be further assume that a thickness of the gate insulation layer 16 is about 80 Å and an applied read voltage Vread of the control gate 20 is about 6.5V. Based on these assumptions, a drain-source channel voltage of the memory cell transistor MCib is lower than a drain-source channel voltage of the memory cell transistor MCia by 0.7V. Therefore, a relatively strong electric field operates in the gate insulation layer 16, causing electrical stress. For example, the electrical field applied to the gate insulation layer 16 of the memory cell transistor MCib is about 6 MV/cm, and the electrical field applied to the gate insulation layer 16 of the memory cell transistor MCia is about 5.1 MV/cm.

As illustrated in FIG. 3, the memory cells receiving the most electrical stress in a conventional read operating mode are the non-selected memory cell transistors MCib connected to a bit line to which 0V is applied (the Non-selected BL) in order to serve as a noise shielding for an adjacent bit line. The channel voltage of each of non-selected memory cells MCia connected to the selected bit line BL is maintained at 0.5V to 0.7V, so a read disturbance is relatively less.

As described above, in a read operation, non-selected memory cell transistors connected to a non-selected bit line have relatively high electrical stress due to low channel voltage. The electrical stress increases the probability of causing read disturbances, especially in highly integrated memories. For example, as a gate oxide layer (e.g., a gate insulation layer) becomes thinner and a distance between a lower part of a control gate and an active region becomes narrower, the electrical stress may incrementally shift a threshold voltage value of a memory cell transistor. As a result, when the memory cell transistor undergoing a shifted threshold voltage value in a read operating mode is selected, read error may be caused by the read disturbance.

Moreover, a memory cell region of a flash EEPROM, in which a read operation is mainly performed, may have a small quantity of code data, such as ROM table information, that requires high speed access or indexing information for stored data of a main memory cell array, etc. When a read disturbance occurs during a read operation in memory cells belonging to the memory cell region, it may be very serious. When a read error occurs due to read disturbance, causing a variation of threshold voltage of memory cells, the data affected by the read error may be difficult to recover to a normal state, even using error correction code logic, etc., thus causing an overall defect of in memory device.

### SUMMARY OF THE INVENTION

An aspect of the present invention provides a nonvolatile semiconductor memory including a floating formation switch coupled to a bit line in a memory cell array. The floating formation switch maintains a channel voltage of memory cells coupled to the bit line at a level above a power supply voltage when the bit line is a non-selected bit line, which reduces electrical stress applied to the memory cells connected to the non-selected bit line during a read operation. The bit line may correspond to a cell string of the memory cell array, the cell string including the memory cells coupled to the bit line. The level above the power supply voltage may be obtained through a self-boosting operation.

The floating formation switch may include a switching transistor coupled between a ground selection transistor and a memory cell positioned farthest from the bit line among the memory cells. The switching transistor may be a same type of transistor as the memory cells or the ground selection transistor.

The floating formation switch may include first and second switching transistors having channels connected in series between a ground selection transistor and a memory cell positioned farthest from the bit line among the memory cells. Each of the first and second switching transistors be a same type of transistor as the memory cells or the ground selection transistor, and may have different threshold voltages. A sequence in which the first and second switching transistors are connected in series to the ground selection transistor may differ based on whether the cell string is an even cell string or odd cell string. Also, at least one of the first and second switching transistors is turned OFF when the bit line is not selected, and both of the first and second switching transistors are turned ON when the bit line is selected, during the read operation.

Another aspect of the present invention provides a nonvolatile semiconductor memory having a memory cell array including multiple cell strings, each cell string including a string selection transistor having a drain connected to a bit line, a ground selection transistor having a source connected to a common source line, and memory cell transistors having channels connected in series between a source of the string selection transistor and a drain of the ground selection transistor. The nonvolatile semiconductor memory includes multiple floating formation switches corresponding to the multiple cell strings. Each floating formation switch maintains a channel voltage of each of the memory cell transistors coupled to a corresponding bit line at a level higher than a power supply voltage when a cell string corresponding to the bit line is not selected. This reduces electrical stress on the memory cell transistors of the corresponding cell string when another cell string of the cell strings in the memory cell array is selected in a read operating mode. Reducing the electrical stress reduces a possibility of a read disturbance of the memory cell transistors.

The level higher than the power supply voltage may be obtained by performing a self-boosting operation of the memory cell transistors when the common source line enters a floating state through a switching operation of the floating formation switch. Each floating formation switch may include a switching transistor connected between the ground selection transistor and a memory cell transistor positioned farthest from the bit line connected to the corresponding cell string. The switching transistor may be a same type of transistor as the string selection transistor or the memory cell transistors.

Each floating formation switch may include first and second switching transistors having channels connected in series between the ground selection transistor and a memory cell transistor positioned farthest from the bit line connected to the corresponding cell string. A sequence in which the first and second switching transistors are connected to the ground selection transistor may differ depending upon whether the corresponding cell string comprises an even cell string or odd cell string. At least one of the first and second switching transistors may be turned OFF when the corresponding cell string is not selected, and both of the first and second switching transistors may be turned ON when the corresponding cell string is selected, in the read operating mode.

Another aspect of the present invention provides a nonvolatile semiconductor memory device, including a memory cell array and a read operation controller. The memory cell array includes multiple cell strings, each of which includes a first selection transistor having a drain connected to a corresponding bit line, a second selection transistor having a source coupled to a common source line, multiple memory cell transistors having channels connected in series to a source of the first selection transistor and which each have a floating gate, and third and fourth selection transistors having channels connected in series to each other between a source of a last memory cell transistor of the memory cell transistors and a drain of the second selection transistor. The third and fourth selection transistors have different threshold voltage values. The read operation controller controls one of the third and fourth selection transistors of one of the cell strings to be turned OFF and a channel voltage of the memory cell transistors of the cell string to be self-boosted to a level above a power supply voltage when a bit-line corresponding to the cell string is not selected. This reduces electrical stress applied to the memory cell transistors belonging to the cell string, when another one of the cell strings is selected in a read operating mode.

The third and fourth selection transistors may be a same type of transistor as the memory cell transistors or the first and second selection transistors.

According to embodiments of the present invention, electrical stress applied to non-selected memory cells connected to a non-selected bit line in a read operating mode can be relatively weakened. Therefore, read error caused by a read disturbance of a nonvolatile memory cell transistor can be prevented or substantially reduced, thereby enhancing reliability in a read operation in a nonvolatile semiconductor memory device.

### BRIEF DESCRIPTION OF THE DRAWINGS

The embodiments of the present invention will be described with reference to the attached drawings, in which:

FIG. 1 is a block diagram of nonvolatile semiconductor memory device, according to a conventional art;

FIG. 2A is a circuit diagram of an equivalent circuit illustrating a connected structure of memory cells in a memory cell array of FIG. 1;

FIG. 2B illustrates an example of bias voltage applied to the equivalent circuit of FIG. 2A in a read operating mode;

FIG. 3 illustrates related-voltage stress in respective memory cells connected to selected-bit line and non-selected bit line of FIG. 2B;

FIG. 4 illustrates a connected structure of memory cell strings, according to exemplary embodiments of the present invention;

FIG. 5 is a circuit diagram of an equivalent circuit illustrating an embodiment of FIG. 4;

FIG. 6 illustrates a related read operation bias voltage applied to the equivalent circuit of FIG. 5;

FIG. 7 is a circuit diagram of an equivalent circuit illustrating another embodiment of FIG. 4;

FIG. 8 illustrates voltage stress in a non-selected memory cell of FIG. 4; and

FIG. 9 is a graph of simulation illustrating a channel voltage boosting effect to prevent a read disturbance in the exemplary embodiments of FIG. 4.

### DETAILED DESCRIPTION OF THE EMBODIMENTS

Embodiments of the present invention will now be described more fully with reference to the accompanying drawings, in which exemplary embodiments of the invention are shown. The invention, however, may be embodied in various different forms, and should not be construed as being limited only to the illustrated embodiments. Rather, these embodiments are provided as examples, to convey the concept of the invention to one skilled in the art. Accordingly, known processes, elements, and techniques are not described with respect to some of the embodiments of the present invention. Throughout the drawings and written description, like reference numerals will be used to refer to like or similar elements.

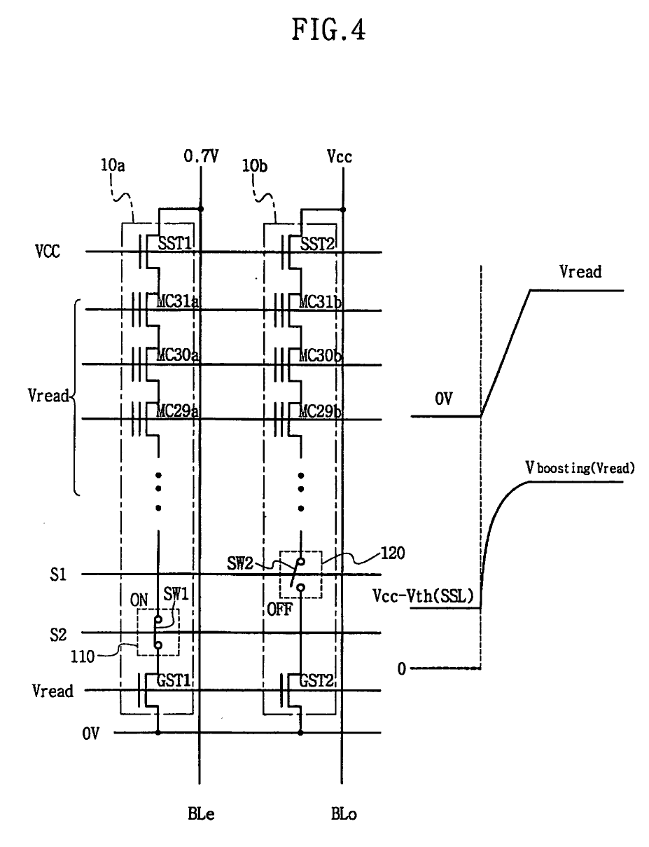

Unless otherwise defined, all terms (including technical and scientific terms) used herein have the same meaning as commonly understood by one of ordinary skill in the art to which this invention belongs. It is further understood that terms used herein should be interpreted as having a meaning that is consistent with their meaning in the context of this specification and the relevant art, and should not be interpreted in an idealized or overly formal sense unless expressly so defined herein. Exemplary embodiments of the present invention are more fully described below with reference to FIGS. 4 to 9. This invention may, however, be embodied in many different forms and should not be construed as being limited to the exemplary embodiments set forth herein. Rather, these exemplary embodiments are provided so that this disclosure is thorough and complete, and conveys the concept of the invention to those skilled in the art.

According to various embodiments of the present invention, a drain-source channel voltage of non-selected memory cells within a non-selected cell string may be increased using a self-boosting operation. Generally, a higher voltage is applied as a precharge voltage for self-boosting to a non-selected bit line, and a floating formation switching unit is adapted to electrically separate a common source line from a cell string in a read operating mode. According to the various embodiments, a nonvolatile semiconductor memory is able to prevent or substantially reduce read error caused by read disturbances.

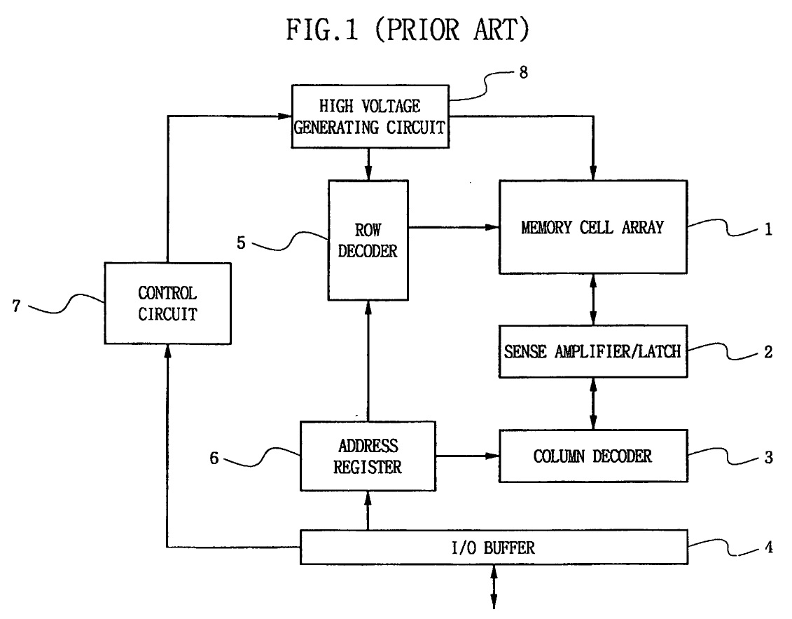

FIG. 4 illustrates a connected structure of memory cell strings according to various exemplary embodiments of the present invention. The memory cell strings are in a memory cell array, which may be incorporated into a nonvolatile semiconductor memory device having other operational elements, such as the sense amplifier/latch 2 and the control circuit 7, for example, as shown in FIG. 1.

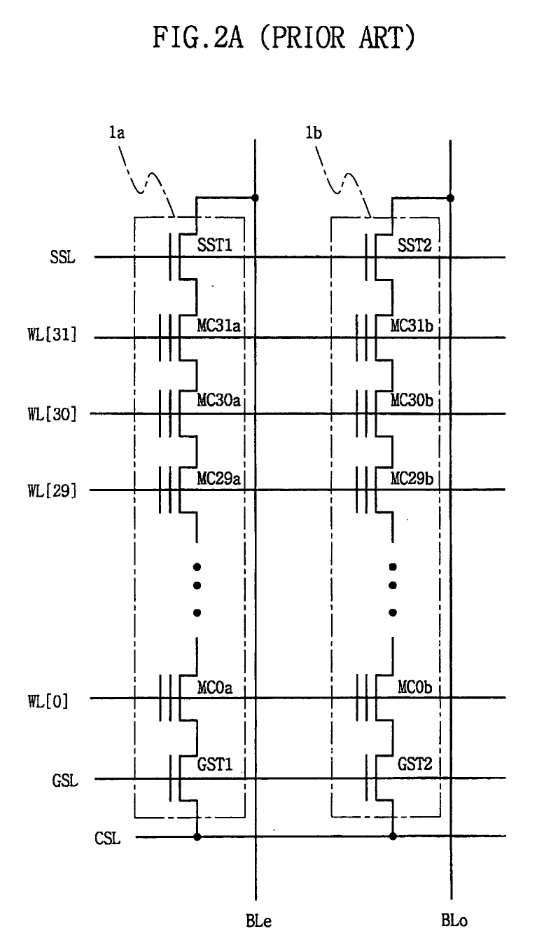

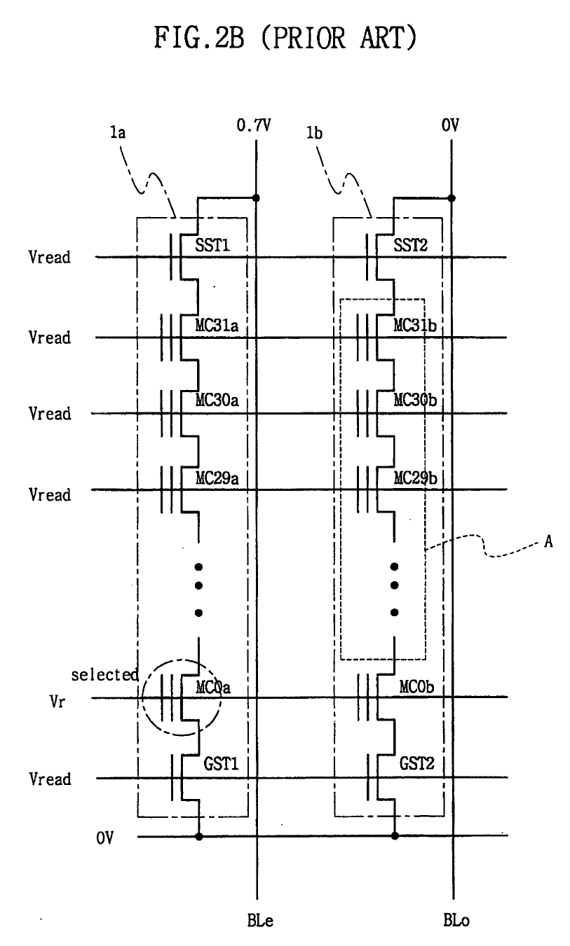

Referring to FIG. 4, an interior connection structure of cell strings constituting a memory cell array is different from that shown in FIG. 2A. Cell strings 10a and 10b include floating formation switching units SW1 and SW2, respectively. The floating formation switching unit (e.g., SW1 or SW2) belonging to a non-selected cell string (e.g., 10a or 10b) during a read operating mode operates so that a channel voltage of each of the memory cells connected to a non-selected bit line is maintained at a level above a power supply voltage. In other words, a floating formation switching unit is included in every cell string of the memory cell array. The floating formation switching unit is switched ON when the bit line corresponding to the cell string is selected and switched OFF when the bit line corresponding to the cell string is not selected.

For example, FIG. 4 depicts when an odd bit line BLo is not selected, in which case a power supply voltage Vcc is applied to the odd bit line BLo, and the floating formation switching unit SW2 of the cell string 10b is switched to the OFF position (120) by a control voltage S1. FIG. 4 further depicts when an even bit line BLe is selected, in which case a voltage 0.7V is applied to the even bit line BLe, and the floating formation switching unit SW1 of the cell string 10a is in the ON position (110).

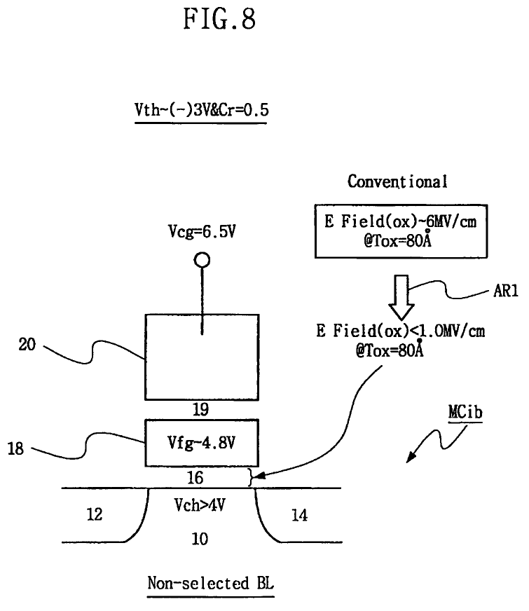

When the floating formation switching unit SW2 is switched OFF, a common source line CSL is electrically separated from the second cell string 10b. At this time, a channel of each non-selected memory cell transistors MC31b, MC30b, . . . , MC1b is in a state of having been precharged to a channel voltage corresponding to VCC-Vth (the threshold voltage of SST2), as shown in the lower graph in FIG. 4. When the read voltage Vread is applied to the control gates of the non-selected memory cell transistors MC31b, MC30b, . . . , MC1b, e.g., after the floating formation switching unit SW2 is switched OFF, the channel voltage increases by a self-boosting operation of the memory cell transistors, as shown in the lower graph. The voltage Vboosting, increased by the self-boosting, depends on a coupling ratio of the memory cell transistors, and is provided as a voltage level over about 4V. Electrical stress applied to a gate insulation layer 16 of the non-selected memory cell transistors MC31b, MC30b, . . . , MC1b, i.e., electric field, drops below about 1.0 MV/cm, as shown in FIG. 8. Accordingly, the electrical stress applied to the non-selected memory cell transistors MC31b, MC30b, . . . , MC1b is significantly weakened, as compared to the electrical stress applied to the non-selected memory cell transistors connected to the selected bit line, thereby substantially reducing or preventing read disturbance.

In FIG. 4, although it was assumed that the odd bit line BLo was not selected, it may be assumed alternatively that the even bit line BLe is not selected, in which case the power supply voltage Vcc is applied to the even bit line BLe in a read operating mode, and a voltage of 0.7V is applied to the odd bit line BLe. At this time, the ON/OFF operation of the switches SW1 and SW2 becomes the opposite of that depicted in FIG. 4. That is, the switch SW1 is OFF and the switch SW2 is ON.

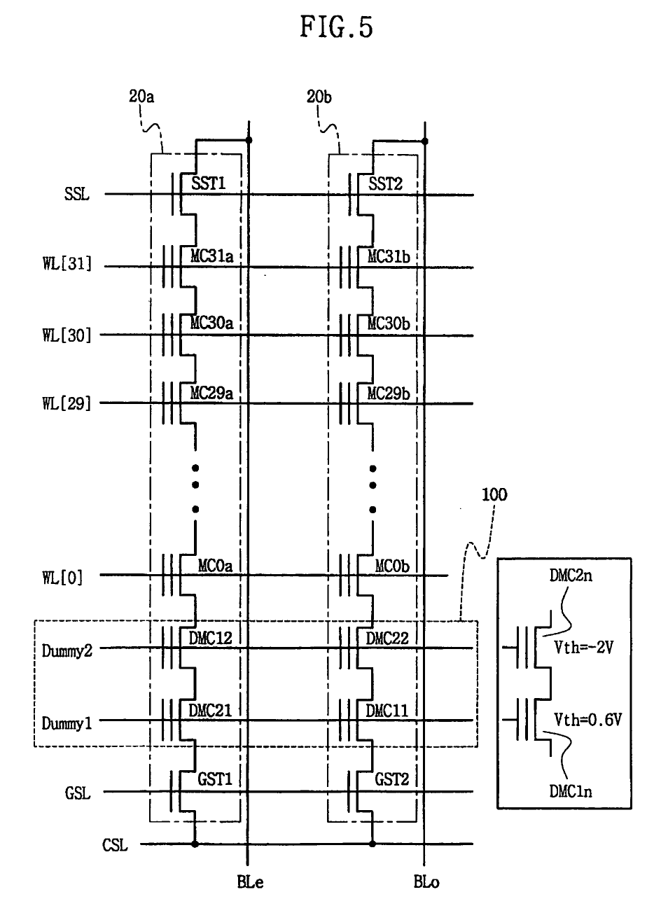

FIG. 5 is a circuit diagram of an equivalent circuit for an embodiment of FIG. 4. With reference to FIG. 5, a first cell string 20a includes a first selection transistor SST1 having a drain connected to a bit line BLe, a second selection transistor GST1 having a source coupled to a common source line CSL, memory cell transistors MC31a, MC30a, . . . , MC0a having channels connected in series to a source of the first selection transistor SST1, and third and fourth selection transistors DMC12 and DMC21 having channels connected in series to each other between a source of a last memory cell transistor MC0a and a drain of the second selection transistor GST1. The third and fourth selection transistors DMC12 and DMC21 have different threshold voltage values. Also, each of the memory cell transistors MC31a, MC30a, . . . MC0a has a floating gate.

Similarly, a second cell string 20b includes a first selection transistor SST2 having a drain connected to the bit line BLo, a second selection transistor GST2 having a source coupled to the common source line CSL, memory cell transistors MC31b, MC30b, . . . , MC0b having channels connected in series to the source of the first selection transistor SST2, and third and fourth selection transistors DMC22 and DMC11 having channels connected in series to each other between a source of a last memory cell transistor MC0b and a drain of the second selection transistor GST2. The third and fourth selection transistors DMC22 and DMC11 have different threshold voltage values. Also, each of the memory cell transistors MC31b, MC30b, . . . , MC0b has a floating gate.

In a dummy cell unit 100, which includes the floating formation switching units (e.g., SW1 and SW2 of FIG. 4), the dummy cell transistors DMC11 and DMC12 are determined to have a threshold voltage of about 0.6V, and the dummy cell transistors DMC21 and DMC22 are determined to have a threshold voltage of about −2V. When the second cell string 20b is not selected, the read voltage Vread is applied as a control voltage Dummy2, and a voltage of about 1V is applied as a control voltage Dummy1, and thus the dummy cell transistor DMC22 is turned ON and the dummy cell transistor DMC11 is turned OFF. Thus, the common source line CSL is not electrically connected to the bit line BLo through the second cell string 20b. On the other hand, the dummy cell transistors DMC12 and DMC21 in the selected cell string 20a are both turned ON, and thus enable a normal read operation for a selected memory cell transistor in the first cell string 20a.

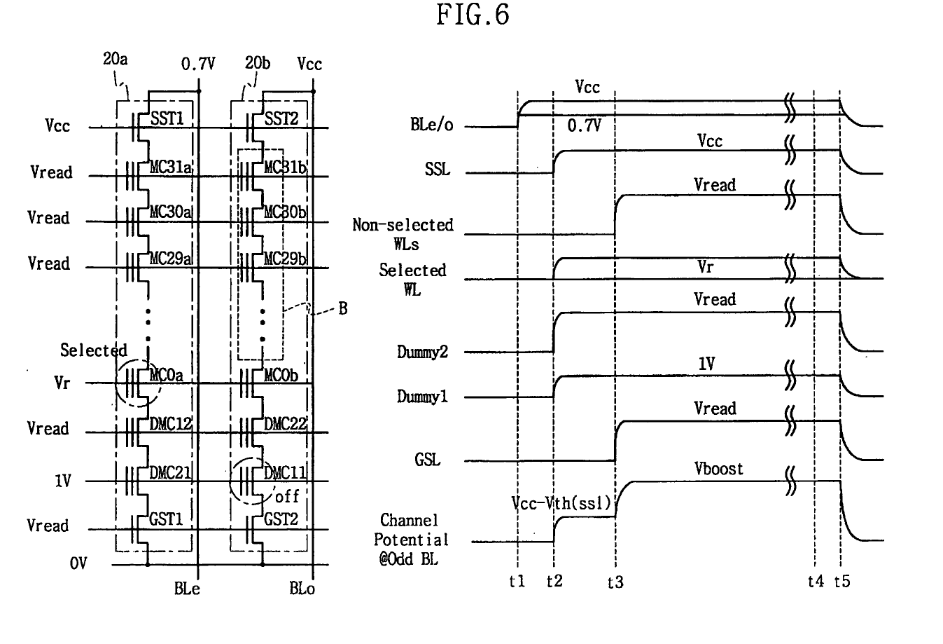

With reference to FIG. 6 illustrating a related read operation bias voltage applied to the equivalent circuit of FIG. 5, channel voltage for non-selected memory cells connected to a non-selected bit line increases by self-boosting.

For example, when in the dummy cell unit 100 of FIG. 5, the dummy cell transistors DMC11 and DMC12 are adjusted to have a threshold voltage of about 0.6V and the dummy cell transistors DMC21 and DMC22 are adjusted to have a threshold voltage of about −2V, a related bias voltage applied to respective parts of the circuit in the read operating mode can be described as follows.

After a read command is applied, at a time point t1, 0.7V is applied to the selected bit line BLe and a power supply voltage Vcc of about 2.6V is applied to non-selected bit line BLo, as shown in the right graph of FIG. 6. At a time point t2, a power supply voltage Vcc is applied to a string selection line SSL. (Conventionally, read voltage Vread was applied to the SSL.) Also, at the time point t2, a selection read voltage Vread is applied to a selected-word line, i.e., WL0. The read voltage Vread is applied as a control voltage Dummy2, and a voltage of about 1V is applied as a control voltage Dummy1. At this point, the dummy cell transistor DMC22 is turned ON, and the dummy cell transistor DMC11 is turned OFF, electrically isolating the second cell string 20b from the bit line BLo. On the other hand, the dummy cell transistors DMC12 and DMC21 in selected-cell string 20a are both turned ON, and a channel of the selected memory cell transistor MC0a is electrically connected between bit line BLe and the common source line CSL. That is, the first cell string 20a has a discharge path, while a discharge path of the second cell string 20b is cut off and so enters a floating state.

Each channel of the non-selected memory cells of the non-selected bit line BLo is precharged to a voltage corresponding to Vcc-Vth (the threshold voltage of SST2) after the time point t2, through the bias condition Bias discussed above. In this state, when read voltage Vread is applied to non-selected word lines WL1-WL31 and a ground selection line GSL at a time point t3, a channel voltage increase appears by a self-boosting operation.

Consequently, as the channel voltage of the non-selected memory cells connected to the non-selected bit line is self-boosted by the read voltage Vread, it appears as a boosting voltage Vboost increased by a boosting ratio in Vcc-Vth. The boosting ratio depends primarily on a coupling ratio of the memory cell transistor, which indicates a rate of capacitance between a second capacitance (C2) between a control gate (CG) and a floating gate (FG) and a first capacitance (C1) between the FG and a bulk/substrate. The coupling ratio Cr may be represented as C2/C1+C2. In an embodiment of the present invention, the coupling ratio Cr is 0.5, and memory cell transistors have a threshold voltage of about −3V in an erase state. In the bias voltage waveforms of FIG. 6, the time points t1 and t2 were indicated as distinct times only for convenience of explanation. There is no particular difference in operating results even in a simultaneous bias occurrence.

The non-selected memory cell transistors connected to the non-selected bit line have much less electrical stress as compared to conventional non-selected memory cell transistors due to the channel voltage being increased by self-boosting. Thus, read disturbance can be prevented or substantially reduced, lowering the possibility of occurrences of read error.

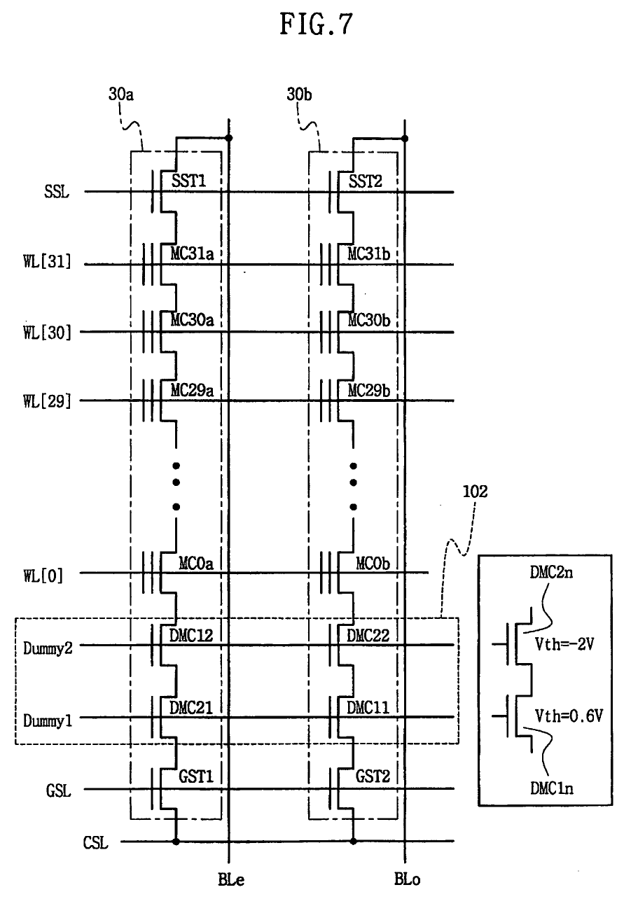

FIG. 7 is a circuit diagram of equivalent circuit illustrating another embodiment of FIG. 4. Unlike FIG. 5, the example in FIG. 7 provides a dummy transistor unit 102 that includes dummy transistors DMC11, DMC12, DMC21 and DMC22 which may be general transistors, such as a string selection transistor SST or a ground selection transistor GST. In other words, the dummy transistor unit 102 is configured as a general MOS transistor, not as a memory cell transistor having a floating gate. As in FIG. 5, each of the dummy cell transistors DMC11 and DMC12 are controlled to have a threshold voltage of about 0.6V, and each of the dummy cell transistors DMC21 and DMC22 are controlled to have a threshold voltage of about −2V.

In FIG. 7, the correlation of bias voltage applied to respective parts of the circuit in a read operating mode is the same as that of FIG. 6. Therefore, the only practical difference is that the floating formation switching unit (e.g., SW1 and SW2) is constructed of transistors, such as string selection transistors, instead of memory cell transistors. Otherwise, it is the same with respect to the channel voltage for non-selected memory cells connected to a non-selected bit line being increased by a self-boosting operation.

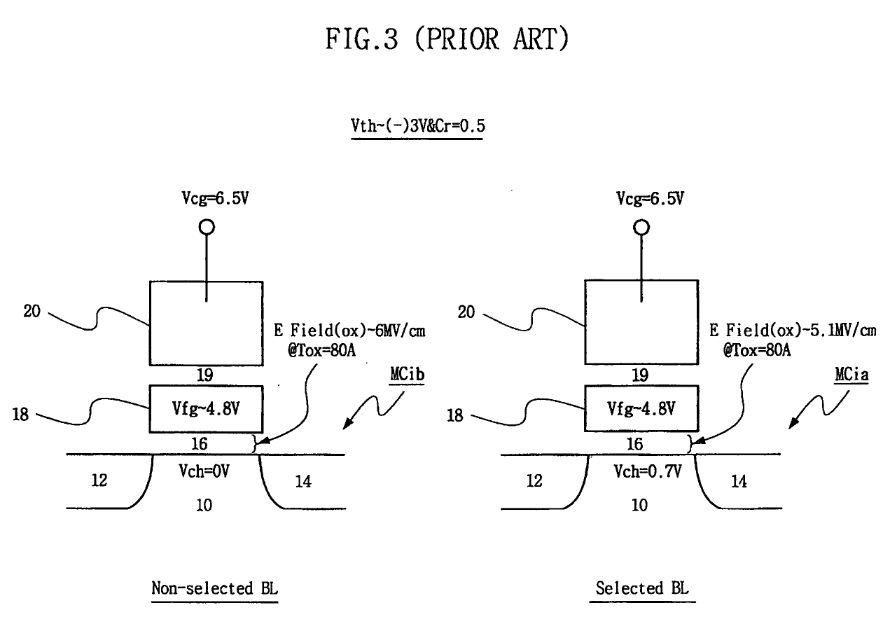

FIG. 8 illustrates voltage stress in a non-selected memory cell coupled to a non-selected bit line, shown in FIG. 4. A channel voltage Vch between a source 12 and a drain 14 exceeds about 4V by the self-boosting effect. As compared to the conventional memory cell transistor MCib of FIG. 3, for example, in which an electrical field of about 6 MV/cm is applied to the gate insulation layer 16, an electrical field of about 1 MV/cm is applied in an embodiment of the present invention. FIG. 8 indicates this comparison by an arrow AR1, which shows the difference in electrical field strength.

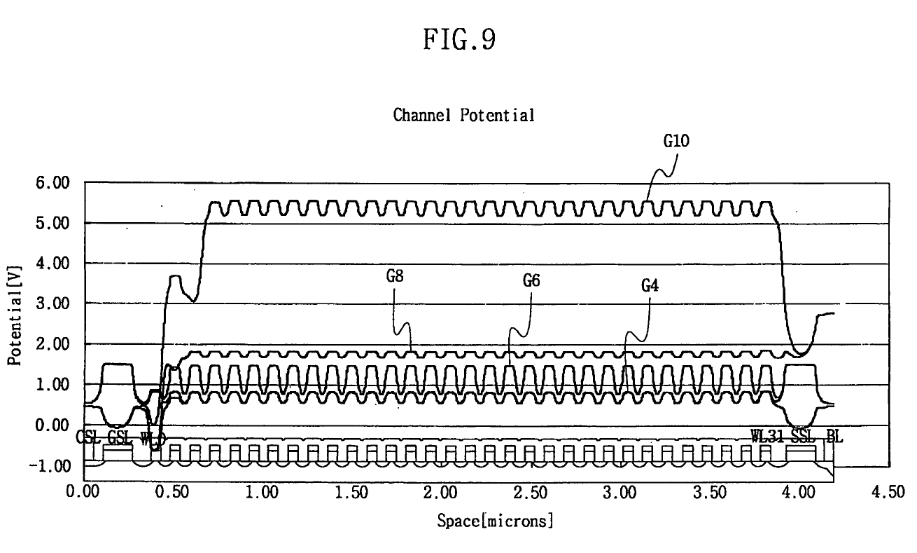

For purposes of further clarifying the embodiments, FIG. 9 provides a graph of simulation illustrating a channel voltage boosting effect to prevent a read disturbance in the connected structure of FIG. 4. In FIG. 9, a transverse axis indicates one cell string having 32 memory cell transistors in microns, and a longitudinal axis indicates a channel voltage of non-selected memory cell transistors connected to a non-selected bit line in volts. A comparison of graph G10 with graph G6 clearly discriminates between an embodiment of the invention which prevents read disturbance and a conventional case which causes a read disturbance. Consequently, a channel voltage between a drain and a source shown in the graph G10 indicates over about 5V with respect to the example embodiment, which is higher than the example of the conventional technique by about 4V. Graph G8 indicates a channel voltage precharged before a self-boosting operation, according to an embodiment of the invention. Graph G4 synthetically indicates a conventional initial operation and operation after an applied power supply voltage, and a channel voltage based on an initial operation according to an embodiment of the invention.

As described above, non-selected memory cell transistors in a non-selected cell string perform a self-boosting operation in a read operating mode, thus the channel voltage of each of the non-selected memory cell transistors increases, as illustrated in FIG. 9. Therefore, the electrical stress applied to a gate insulation layer 16 of the non-selected memory cell transistors MC31b, MC30b, . . . , MC1b, that is, the electrical field, is less than about 1.0 MV/cm, as shown in FIG. 8, thereby substantially reducing or preventing read disturbances.

A nonvolatile memory device having the configuration of a memory cell array shown in FIG. 5 or FIG. 7 may also include an erase circuit for performing an erase operation, returning a data maintenance characteristic of the memory cells to an initial state, for example, in the control circuit 7 of FIG. 1. Further, the nonvolatile memory device may include a program circuit for storing data in the normal memory cells that have undergone the erase operation, for example, in the control circuit 7 of FIG. 1.

Erase, write and read operations of a NAND-type EEPROM are performed as follows. The erase and program (write) operations can be performed by using an F-N tunneling current. For example, in the erase operation, a very high potential is applied to a substrate and a low potential is applied to the control gate (CG). In this case, potential determined by a coupling ratio for a capacitance between the CG and the floating gate (FG) and a capacitance between the FG and the substrate is applied to the FG. When a potential difference between a floating gate voltage Vfg applied to the FG and a substrate voltage Vsub applied to the substrate is greater than a potential difference creating the F-N tunneling, electrons gathered in the FG move to the substrate. Such operation lowers a threshold voltage Vt of a memory cell transistor constructed of CG, FG, a source and a drain. The Vt is sufficiently lowered, and so current flows when an appropriate amount of voltage is applied to the drain, even though 0 V is applied to the CG and the source, which may be called “ERASED” and is typically indicated as logic “1.”

Meanwhile, in the write operation, 0V is applied to the source and the drain, and a very high voltage is applied to the CG. At this time, an inversion layer is formed in a channel region, and the source and the drain both have a potential of 0V. When a potential difference between Vfg, determined by a ratio of capacitances between the CG and the FG and between the FG and the channel region, and Vchannel (0 V) becomes great enough to create the F-N tunneling, electrons move from the channel region to the FG. In this case, the Vt increases, and when a predetermined amount of voltage is applied to the CG, 0V is applied to the source, and an appropriate amount of voltage is applied to the drain, current does not flow. This may be called “PROGRAMMED” and is typically indicated as logic “0.”

In a memory cell array having multiple cell strings, such as the first and second cell strings, a “page” indicates a set of memory cell transistors in which control gates are connected in common to one word line. Multiple pages including multiple memory cell transistors are provided as a cell block, and one cell block typically includes one or multiple cell strings per bit line. One NAND flash memory has a page program mode for a high speed programming. A page program operation is classified as a data loading operation and a program operation. The data loading operation sequentially latches and stores data of a byte magnitude in data registers from input/output terminals. The data registers correspond to respective bit lines. The program operation writes at a time data stored in the data registers to memory transistors on a word line selected through bit lines.

In the NAND-type EEPROM described above, read and program operations are generally performed in page units, and an erase operation is performed in a block unit. Actually, electron movement between a channel and an FG of the memory cell transistor occurs only in program and erase operations. In a read operation, data stored in a memory cell transistor is simply read without damaging the data after the program and/or erase operations.

The bias voltage condition shown in FIG. 6 corresponds to the read operation. A voltage (generally, the read voltage), higher than a selection read voltage Vr applied to the CG of a selected memory cell transistor, is applied to the CG of a non-selected memory cell transistor. Then, current flows or does not flow in a corresponding bit line according to a program state of the selected memory cell transistor. When a threshold voltage of a programmed memory cell is higher than a reference value under a predetermined voltage condition, the memory cell is determined to OFF, and a corresponding bit line is charged to a high level voltage. To the contrary, when the threshold voltage of the programmed memory cell is lower than the reference value, the memory cell is determined to be ON, and the corresponding bit line is discharged to a low level. The state of the bit line is read out as a “0” or a “1” through a sense amplifier called a page buffer.

Multiple memory cell transistors in an EEPROM initially perform an erase operation to have a threshold voltage, e.g., under about −3V. When a high voltage is applied to a word line of a selected memory cell for a given time, the selected memory cell is changed to a higher threshold voltage. Meanwhile, threshold voltages of non-selected memory cells in a programming operation are not changed.

According to the embodiments of the present invention described above, read disturbances in non-selected memory cell transistors connected to a non-selected bit line can be substantially reduced or prevented during a read operation, thus reducing the probability of read error.

Further, according to the embodiments of the present invention described above, in a nonvolatile semiconductor memory and in a driving method of the nonvolatile semiconductor memory, electrical stress applied to non-selected memory cells coupled to a non-selected bit line in a read operation is relatively reduced. Accordingly, read error caused by read disturbances of the nonvolatile memory cell transistor can be prevented or substantially reduced, enhancing reliability of the read operation in nonvolatile semiconductor memory devices.

While the present invention has been described with reference to exemplary embodiments, it will be apparent to those skilled in the art that various changes and modifications may be made without departing from the spirit and scope of the present invention. For example, the number of transistors constituting a memory cell string or a floating formation switching unit, and the configuration of the device or operating conditions may vary. Accordingly, these and other changes and modifications are seen to be within the spirit and scope of the present invention.

Therefore, it is understood that the above embodiments are not limiting, but illustrative. In the drawings and specification, there have been disclosed typical embodiments of the invention and, although specific terms are employed, they are used in a generic and descriptive sense only and not for purposes of limitation.

What is claimed is:

1. A nonvolatile semiconductor memory comprising:
a floating formation switch coupled to a bit line in a memory cell array, the floating formation switch maintaining a channel voltage of memory cells coupled to the bit line at a level above a power supply voltage when the bit line comprises a non-selected bit line, reducing electrical stress applied to the memory cells during a read operation.

2. The memory of claim 1, wherein the bit line corresponds to a cell string of the memory cell array, the cell string comprising the memory cells coupled to the bit line.

3. The memory of claim 1, wherein the level above the power supply voltage is obtained through a self-boosting operation.

4. The memory of claim 2, wherein the floating formation switch comprises a switching transistor coupled between a ground selection transistor and a memory cell positioned farthest from the bit line among the memory cells.

5. The memory of claim 4, wherein the switching transistor comprises a same type of transistor as the memory cells or the ground selection transistor.

6. The memory of claim 2, wherein the floating formation switch comprises first and second switching transistors having channels connected in series between a ground selection transistor and a memory cell positioned farthest from the bit line among the memory cells.

7. The memory of claim 6, wherein each of the first and second switching transistors comprises a same type of transistor as the memory cells or the ground selection transistor.

8. The memory of claim 7, wherein the first and second switching transistors have different threshold voltages.

9. The memory of claim 8, wherein a sequence in which the first and second switching transistors are connected in series to the ground selection transistor is different based on whether the cell string comprises an even cell string or odd cell string.

10. The memory of claim 9, wherein at least one of the first and second switching transistors is turned OFF when the bit line is not selected, and wherein both of the first and second switching transistors are turned ON when the bit line is selected, during the read operation.

11. A nonvolatile semiconductor memory having a memory cell array comprising a plurality of cell strings, each cell string comprising a string selection transistor having a drain connected to a bit line, a ground selection transistor having a source connected to a common source line, and a plurality of memory cell transistors having channels connected in series between a source of the string selection transistor and a drain of the ground selection transistor, the nonvolatile semiconductor memory comprising:
a plurality of floating formation switches corresponding to the plurality of cell strings, each floating formation switch maintaining a channel voltage of each of the plurality of memory cell transistors coupled to a corresponding bit line at a level higher than a power supply voltage when a cell string corresponding to the bit line is not selected, reducing electrical stress on the memory cell transistors of the corresponding cell string when another cell string of the plurality of cell strings in the memory cell array is selected in a read operating mode.

12. The memory of claim 11, wherein reducing the electrical stress reduces a possibility of a read disturbance of the plurality of memory cell transistors.

13. The memory of claim 11, wherein the level higher than the power supply voltage is obtained by performing a self-boosting operation of the plurality of memory cell transistors when the common source line enters a floating state through a switching operation of the floating formation switch.

14. The memory of claim 11, wherein each floating formation switch comprises a switching transistor connected between the ground selection transistor and a memory cell transistor of the plurality of memory cell transistors positioned farthest from the bit line connected to the corresponding cell string.

15. The memory of claim 14, wherein the switching transistor comprises a same type of transistor as the string selection transistor or the memory cell transistors.

16. The memory of claim 11, wherein each floating formation switch comprises first and second switching transistors having channels connected in series between the ground selection transistor and a memory cell transistor of the plurality of memory cell transistors positioned farthest from the bit line connected to the corresponding cell string.

17. The memory of claim 16, wherein a sequence in which the first and second switching transistors are connected to the ground selection transistor differs depending upon whether the corresponding cell string comprises an even cell string or odd cell string.

18. The memory of claim 17, wherein at least one of the first and second switching transistors is turned OFF when the corresponding cell string is not selected, and both of the first and second switching transistors are turned ON when the corresponding cell string is selected, in the read operating mode.

19. A nonvolatile semiconductor memory device, comprising:
a memory cell array comprising a plurality of cell strings, each cell string comprising a first selection transistor having a drain connected to a corresponding bit line, a second selection transistor having a source coupled to a common source line, a plurality of memory cell transistors having channels connected in series to a source of the first selection transistor and which each have a floating gate, and third and fourth selection transistors having channels connected in series to each other between a source of a last memory cell transistor of the plurality of memory cell transistors and a drain of the second selection transistor, the third and fourth selection transistors having different threshold voltage values; and
a read operation controller for controlling one of the third and fourth selection transistors of one of the plurality of cell strings to be turned OFF and a channel voltage of the memory cell transistors of the cell string to be increased to be self-boosted to a level above a power supply voltage when a bit-line corresponding to the cell string is not selected, reducing electrical stress applied to the memory cell transistors belonging to the cell string, when another one of the plurality of cell strings is selected in a read operating mode.

20. The device of claim 19, wherein the third and fourth selection transistors comprise a same type of transistor as the memory cell transistors or the first and second selection transistors.
